(19) United States
(12) Patent Application Publication
(10) Pub. No.: US 2005/0217993 A1
(43) Pub. Date: Oct. 6, 2005

(54) Lock chamber device for vacuum treatment unit and procedures for its operation

(75) Inventors: Thomas Gebele, Freigericht (DE); Jurgen Henrich, Limeshain (DE); Manfred Weimann, Alzenau (DE)

Correspondence Address: PRICE HENEVELD COOPER DEWITT & LITTON, LLP, 695 KENMOOR, S.E., P O BOX 2567, GRAND RAPIDS, MI, 49501, US

(73) Assignee: Applied Films GmbH & Co. KG

(21) Appl. No.: 11/093,799

(22) Filed: Mar. 30, 2005

(30) Foreign Application Priority Data
Mar. 31, 2004 (EP) 04 007 820.6

(51) Int. Cl. C23C 16/00; C23C 14/35

(52) U.S. Cl. 204/298.25; 118/719

(57) ABSTRACT

A multistage lock chamber device with at least two lock chambers, a first pump set for evacuating a first lock chamber, and a second pump set for evacuating a second lock chamber. The first pump set (P1) may evacuate both the first and the second lock chamber, or both jointly. The first pump set may also be utilized as a prior pumping stand of the second pump set. Additionally, an integrated third pump set can be utilized as a pre-pumping stand for the second pump set and/or first pump set. Alternately or additionally, the device can include at least one buffer unit, whose buffer volume is being utilized to produce a sudden decline in pressure inside the lock chamber by means of pressure equalization.

### CROSS-REFERENCE TO RELATED APPLICATION

This application claims priority to European Patent Application No. 04007820.6, filed on Mar. 31, 2004, entitled LOCK CHAMBER DEVICE FOR VACUUM TREATMENT UNIT AND PROCEDURES FOR ITS OPERATION.

### FIELD OF THE INVENTION

The present invention refers to a lock chamber device and to a process for operating a multistage lock chamber device.

### BACKGROUND OF THE INVENTION

Glass panels are being coated, for example, in vacuum coating plants, under high-vacuum conditions, at pressures within the range of 5×10⁻⁴ hPa to 1×10⁻² hPa, especially within the range of 3×10⁻³ hPa for sputtering processes. In order to increase plant productivity figures and to avoid the requirement of having to evacuate the entire installation for each substrate and, especially, the high-vacuum section, load and unload locks are being used for the substrates.

In order to improve the material flux rate and increase productivity figures, in modern in-line coating plants, separate load and unload lock chambers are being used. A simple so-called 3-chamber coating unit consists of a load lock, in which the substrate is being pumped from atmospheric pressure to an adequate transition pressure of, for example, p=5E-2 hPa, of a sequential vacuum coating section (process chamber) and an unload lock, in which, by means of ventilation, said substrate is again being adjusted to the atmospheric pressure level.

The task of lock chambers is to evacuate as quickly as possible to a sufficient and lowest possible transition pressure to the process range. While ventilation may take place in a few seconds without utilizing pumps for evacuating purposes, a certain vacuum pump stand must be connected to the lock chamber.

A factor in productivity and concurrent economical utilization of an in-line coating unit is the so-called cycle, i.e., station time, i.e., the time which has to be used per batch of substrate before the next batch of substrate may be introduced into the unit, or the average processing time per substrate batch under continuous operating conditions. In order to achieve, for example, a cycle time of two minutes, the lock chamber must be in condition to deliver within t≦2 minutes a substrate from a given atmospheric point A to a given point B within the (high) vacuum range, and vice versa. For this purpose, the system must transport said substrate into and out of the lock chamber, evacuate and ventilate said lock chamber, respectively, and open and eventually close all applicable valves. This means that in such a case, the time available for evacuation is always more reduced than the cycle time (for example, 90 s of 120 s), since also all other tasks (see above) have to be accomplished within said cycle time.

According to the known relation:

$$t = \frac{V}{S} \cdot ln ( \frac{{P}_{o}}{{P}_{1}} )$$

with t=pump time
V=volume
S=pumping capacity
Pₒ=start pressure (atmospheric pressure)
P₁=target pressure (transfer pressure, lock reversing pressure),
   it becomes evident that there are clearly two possibilities to reduce the pump time and consequently also the cycle time: volume reduction of lock chamber; or increase of pumping capacity coupled to the lock chamber.

Since both possibilities have technical and economical limits, in these in-line coating plants with high productivity rates and corresponding reduced cycle time, measures have been taken to subdivide the evacuation/ventilation process into two or more lock chambers. For the inlet side, this means, for example, that within a primary load lock, evacuation takes place from atmospheric pressure until an intermediate pressure of, for example, 10 hPa, while in a secondary lock chamber, this action takes place from the intermediate pressure (i.e., equalization pressure) until the transfer pressure, for example 5E-2 hPa. In such a 5-chamber unit (2 load locks, 2 unload locks, 1 process chamber), the loading and unloading action is being split up between two chambers and, thus, takes place in two steps, being distributed in two cycles. Thus, for example, in architectural glass panel coating units, with a lock chamber volume of approximately 2 m³ to 5 m³, it was possible to reduce the cycle time from approximately 60 s to 90 s, to approximately 40 s to 50 s. In order to attain still shorter cycle times, for example, t<30 s, the two-stage transfer principle was complemented with another step and plants were built with three of each of load and unload lock chambers. These so-called 7-chamber units and also the fast 5-chamber units, compared to the 3-chamber units, offer the specific feature that the mere pump time (evacuation time) takes up only approximately half (e.g., 17 s of 35 s) or, in still faster units, for example, only 25% of the cycle time (5 s of 20 s), while with slower and older units, the pump time still covered the largest part of the cycle time (e.g., 60 s of 90 s). According to prior art, to each lock chamber (lock stage) a vacuum pump stand is assigned, corresponding to the respective operational range, for example, assigning to the first load lock chamber (1) an atmosphere-friendly pump stand for the pressure range of 1000 hPa to, for example, 10 hPa, while for the second load lock chamber (2), a multistage, for example a 3-stage, Roots pump stand for the pressure range of 10 hPa to 2E-2 hPa was assigned.

U.S. Pat. No. 4,504,194 discloses an apparatus for high speed vacuum pumping of an air lock. For this purpose, an expansion tank with a volume larger than the volume of the air lock is provided. The expansion tank is evacuated by a vacuum pump connected to the expansion tank. However, the apparatus is only suitable for lock chambers having a small volume, and for processes where the processing period is long compared with the evacuation period. Using the apparatus in units with large volume lock chambers, e.g., in architectural glass panel coating units, is not feasible.

### SUMMARY OF THE PRESENT INVENTION

It is, thus, a task of the present invention to improve the operational efficiency of a lock chamber unit for vacuum coating plants, especially of the existing 5-chamber or 7-chamber systems, respectively, being thus improved with two, up to three, load and unload lock chambers, as well as with a process chamber, and especially achieving shorter evacuation times and thus shorter cycle times for the lock chamber unit. In view of the improved operational efficiency, the costs for the pump sets of the lock chambers should also be reduced, i.e., lock chambers should be saved, which, again, should offer a cost and space advantage. Another aspect of the present invention comprises attaining lower transition pressures at given cycle and pump times.

Based on a first aspect, the present invention is based on the recognition that the operational capacity of the pump sets and, thus, the time for evacuation of lock chambers may be improved, i.e., reduced, when said pump sets are variably adapted to the individual load lock chambers, since a highest possible use of the pump sets is being envisaged. It is thus possible, by utilizing existing pressure pumps, to achieve an increase of the effective pumping capacity, i.e., a shorter transfer of the substrate from one load lock chamber to another chamber. According to an aspect of the present invention, it is no longer rigidly considered that a pump unit is available for a certain load lock chamber, but an aspect of the present invention includes that different pump sets may be adequately grouped, united or regrouped reciprocally during the inlet process, in order to attain an ideal pump capacity, i.e., to render feasible an earliest possible transfer from one lock chamber to another chamber, at transfer pressures still at a high level.

Accordingly, a first pump unit, primarily designed for a primary lock chamber, will not only be used for this chamber, but also for a second lock chamber, and only corresponding connections will have to be provided from the pump unit to the first lock chamber and to the second lock chamber. Accordingly, it is thus possible to offer the pumping capacity, i.e., absorbing capacity, of the first pump unit either to the first load lock chamber or to the second load lock chamber or to both chambers simultaneously.

Additionally, this first pump set is not only assigned directly or indirectly to the second load lock chamber, but the first pump set, according to a preferred alternate embodiment, will be sequentially added to said load lock chamber on an additional or alternate, basis, as a pre-pumping stage for a second pump set, primarily designed for evacuation of the second lock chamber.

It is thus possible to further expand the possibilities of utilization of the first pump set, providing a more efficient pumping capacity distribution.

According to another embodiment of the present invention, a third pump set is being used, which, as a sequentially added pumping stage for the second pump set, especially in the area of the lock chamber with lower pressures, reinforces the second pump set, especially when the first pump set is no longer available as a pre-pumping stage, since it should be primarily used for the first lock chamber.

Alternately to the above, according to another embodiment, a third pump set may be assigned as a common pre-pumping stage for the first pump set and the second pump set, and the third pump set may be utilized either as a pre-pumping stage for the first pump set or for the second pump set or jointly for both. It is also thus insured that the third pump, similar to the first pump set, may offer to the load lock chambers an altered pumping capacity, especially during the loading process. Accordingly, the pumping capacity obtained will thus be utilized to reduce the evacuation time or lower transfer pressure rates will become feasible.

According to another advantageous embodiment of the present invention, in the case of pumps of a pump set adjacently connected in a parallel direction, a corresponding by-pass may be foreseen, so that by activating/liberating said by-pass and adequate separation of the remaining connecting conduits, this pump is being sequentially connected to the prior parallel connected pumps, in order to produce a multistage pumping stand. This offers the advantage that according to the required pumping capacity, e.g., pressure conditions, by simple re-grouping of the pumps, the pumping capacity may be adjusted according to requirements. For example, in the event that the first pump set is available as a pre-pumping stage for the second pump set, the corresponding pump may be operated parallel with the other pumps in the second pump set, while upon deactivation of the first pump set, as a pre-pumping stage, the pump with the by-pass will be sequentially connected to the other pumps of the second pump set, in order to compound a multistage pumping stand with these sets.

According to another advantageous embodiment, in the case of pumps connected in an adjacent parallel position, especially pumps of the second pump set for the second lock chamber, in a position parallel to said pumps, a differential pressure bypass lid may be integrated, so that the parallel pump sets, especially the second pump set, may be automatically operated according to the prevailing pressure conditions also in the case of high intake pressures. Due to the action of a differential bypass lid, the outlet section of the parallel integrated pumps is being connected with the aspiration section, for example, over the second lock chamber, in order to provide a maximum differential pressure. The maximum compression rate of the parallel integrated pumps and, consequently, also their capability of mechanical and electrical acceptance, are being limited, so that these pumps may be used already at considerably higher intake pressures than without a differential pressure bypass lid. As a consequence, such parallel integrated pumps, such as, for example, Roots pumps, may accompany the pumping action also at relatively high pressure rates, offering their pumping capacity in a prior pumping evacuation phase. It is, thus, possible to waive complex pumps for the second pump set, such as, for example, Roots pumps, cooled before the inlet phase, which may control a high admissible differential pressure of, for example, >800 hPa. Additionally, it is thus also possible to let the second pump set be permanently connected with the second lock chamber, without the need of closing corresponding valves in the conduits leading to the lock chamber. This also provides a better utilization rate of the pumps of the second pump set (an altogether more simple design of the pump set). Instead of only one parallel integrated differential by-pass lid, each pump may have its own differential pressure bypass lid, or it is possible to use pumps with integrated (differential pressure) bypass lids.

Evidently, the different pump sets may encompass one or various parallel reciprocally integrated, single or multistage, vacuum pumps, such as, for example, oil-sealed or dry-compressing vacuum pumps, especially rotary vane pumps, rotary piston pumps, rotary plunger pumps, Roots vacuum booster, dry running pumps, especially axial pumps, Roots pumps, especially pre-admittance-cooled Roots pumps, etc.

Due to the variable embodiment of the pumping capacity, it is especially also possible to completely waive oil-sealed pump sets, utilizing only dry-compressing vacuum pumps, such as, for example, axial pumps.

According to another aspect of the present invention, an acceleration of the transfer process is attained by providing buffer devices, which offer a buffer volume, which, for example, is being evacuated during occasions when the pumping capacity of certain pump sets is not required for the immediate evacuation process, or when direct outlet action is not yet feasible. The absorption capacity, i.e., the pumping capacity, is thus being stored in the buffer set and, at the right moment, it is being offered to the lock chambers by a sudden pressure equalization, for the purpose of evacuation, i.e., pressure reduction of lock chambers. The sudden pressure equalization enables a considerably fast evacuation within fractions of seconds, i.e., practically on a “zero time” basis.

Preferentially, for each lock chamber, a specific buffer device may be provided with a corresponding buffer volume, and additionally to these external buffer devices, the lock chambers specifically also may act as buffers, when the lock chamber, closest to the vacuum area, is previously being evacuated and subsequently, with a preceding lock chamber, providing a pressure equalization for a sudden pressure reduction.

The external buffer devices may be equipped with separate pump sets, however, it is especially convenient to utilize existing pump sets, already provided for the lock chambers, separately or additionally to separate pump sets of said buffer devices. An optimal utilization of said lock chamber pump sets may thus be assured.

It is evident for those skilled in the art that the measures described may be materialized both on the load, as well as on the unload side of the lock.

Other advantages, features and characteristics of the present invention will become clear based on the subsequent, detailed description of preferred embodiments, based on the attached drawings.

### BRIEF DESCRIPTION OF THE DRAWINGS

The drawings indicate in a merely schematic form:

FIG. 1 is a schematic representation of the inlet section of a glass coating unit, with corresponding pump set;

FIG. 2 is another embodiment of a lock chamber with an inlet section, comparable to representation of FIG. 1;

FIG. 3 is a third embodiment of an inlet section with a representation similar to FIG. 1; and

FIG. 4 is another embodiment of a lock chamber.

### DETAILED DESCRIPTION OF THE PREFERRED EMBODIMENTS

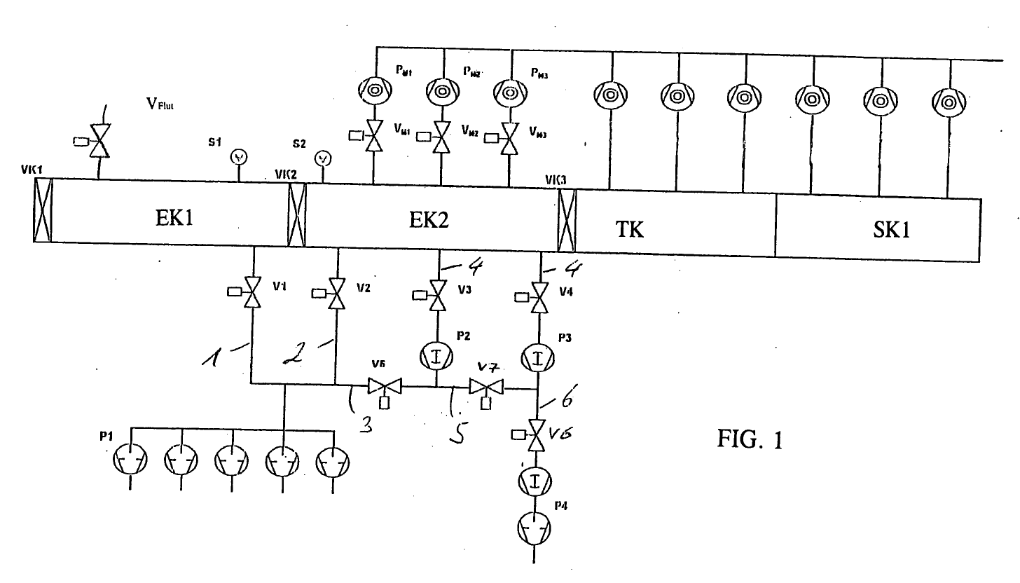

FIG. 1 features a schematic representation of the inlet section of a vacuum treatment plant, in the present case a glass coating plant, with two inlet chambers EK1 and EK2, as well as a transfer chamber TK and a sputtering chamber SK1. The sputtering chamber SK1 and the transfer chamber TK feature a plurality of high-vacuum pumps, in order to adjust high-vacuum conditions for the coating area.

The inlet chambers EK1 and EK2 are separated against the outer environment by means of valve flap VK1, and against said transfer chamber TK by means of valve flap VK3. Amongst said devices, separation is being produced by valve flap VK2.

A valve V_{Flut} for ventilating said inlet chamber EK1 is provided at said inlet chamber EK1.

Additionally, at inlet chamber EK1, a first pump set P1 is provided with five parallel integrated rotary vane pumps, connected with inlet chamber EK1 over conduit 1 and valve V1. Furthermore, pump set P1 is connected with inlet chamber EK2 through conduit 2 and valve V2. Also, through conduit 3, which may be closed through valve V5, pump set P1 is connected with the second pump set P2, P3, formed by parallel integrated Roots pumps P2 and P3.

Roots pumps P2 and P3 of the second pump set are interconnected through conduit 5 at the outlet side, and conduit 5 may be locked over valve V7. Pumps P2 and P3 are also connected with said inlet chamber EK2 through conduits 4 and valves V3 and V4 therein integrated. Additionally, the third pump set P4 is being provided based on a double-stage Roots pump stand with a Roots pump and subsequently integrated rotary vane pump, connected through conduit 6, featuring valve V6, with the second pump set and here especially with conduit 5.

Furthermore, at inlet chamber EK2, high-vacuum pumps are provided, reciprocally connected in parallel projection and which over valves V_{H1} through V_{H3}, may be coupled with inlet chamber EK2.

The inlet process in such a lock chamber unit takes place in such a fashion that initially valve lid VK1 of the first inlet chamber EK1 is being opened and substrate is being transported into the inlet chamber EK1. Subsequently, valve lid VK1 will be closed and valve V1 will be opened towards pump stage P1, so that inlet chamber EK1 may be evacuated.

Subsequently, valves V3, V4 and V5 are being closed and valve V2, as well as valve lid VK2, are being opened. This takes place, for example, with a pressure of 200 hPa. Simultaneously, the substrate is now being moved from the first inlet chamber EK1 towards the second inlet chamber EK2.

Once an adequate pressure level has been attained, for example of 80 hPa, valves V5 and V3 will be opened and valves V1 and V2 will be closed. Simultaneously, or with reduced delay, valves V4 and V7 will be opened. Also, valve V6 will now be opened, this valve V6, however, being provided on an optional basis, having to be present only with a certain type of the pump stand P4. If, for example, the third pump set P4 is being composed by a forepump and a Roots pump with a bypass conduit, said optional valve V6 may be waived, since, in this case, the third pump set P4 may be activated and continuously operated at atmospheric or very high intake pressures, for example of 100 hPa up to 300 hPa.

Subsequently, valves V1 and valve lid VK2 are being closed, so that inlet chamber EK1 may again be ventilated and valve lid VK1 may be opened, in order to accept the next substrate in inlet chamber EK1.

Also, valve V5 is now being closed, so that the first pump set P1 no longer operates as a forepump stand for the second pump set P2, P3, i.e., parallel in relation to the third pump set P4, but not only the third pump set P4, as a retaining pump stand, is subsequently connected to the second pump set P2, P3, while due to opening of valve V1, the first pump set will again be utilized for evacuating the first inlet chamber EK1.

In the second inlet chamber EK2, the optional high-vacuum valves V_{H1} to V_{H3} may now be opened, in order to regulate said inlet chamber EK2 at high-vacuum conditions. With an approximate pressure stand of 0.3 hPa, valves V3 and V4 may be closed and after the corresponding vacuum conditions have been attained, for example with a pressure of 2×10⁻³ hPa, valve lid VK3 may be opened, in order to transfer the substrate into the processing area (transfer chamber).

It is important during this phase that the above described procedures take place inside, i.e., with the two inlet chambers partly in a simultaneous fashion, so that a lowest possible cycle time is being reached. Due to the fact the first pump set P1 is connected not only with inlet chamber EK1, but also with the second inlet chamber EK2, the first pump set P1 may be utilized for a longer period of time, in order to contribute towards a shorter inlet, i.e., admission, time.

It is an advantage of the unit described, i.e., of said procedure, that valve lid VK2 between inlet chamber EK1 and inlet chamber EK2 cannot be opened only at acceptance pressure of the Roots pumps P2 and P3 of the second pump set, i.e., at approximately 15 hPa, but this may take place already at higher pressures, in the range of 100 hPa through 200 hPa, especially 150 hPa. Pumping times will, thus, be cut down inside inlet chamber EK1 by approximately one third, or pump set P1 could be reduced by a third, relative to the pumping capacity.

Additionally, it is advantageous that the first pump set P1 may be used with pumps P2 and P3, through valve V5, as a forepump stand of the second pump set, so that the second pump set with pumps P2 and P3 may be used at much higher pressures. A utilization rate of approximately 100 hPa, instead 10 hPa, will now become feasible.

Especially, opening and closing times of the different valves, especially opening of V5, V7, V3 and V4, as well as closing of V2, may be reciprocally synchronized in such a fashion, that no interruption of the pumping capacity is caused and commuting times of cycle times are, thus, not being negatively influenced.

The third pump set P4 is designed to form with the second pump set P2, P3, a multi-stage pump stand, until the necessary transfer pressure, i.e., activation pressure, for the optional high-vacuum pumps P_{H1} to P_{H3} has been attained. Also, the third pump set P4 is designed to reinforce the second pump set P2, P3, when the first pump set P1 is being required for evacuating said inlet chamber EK1, thus no longer being available as a forepump stand for the second pump set P2, P3.

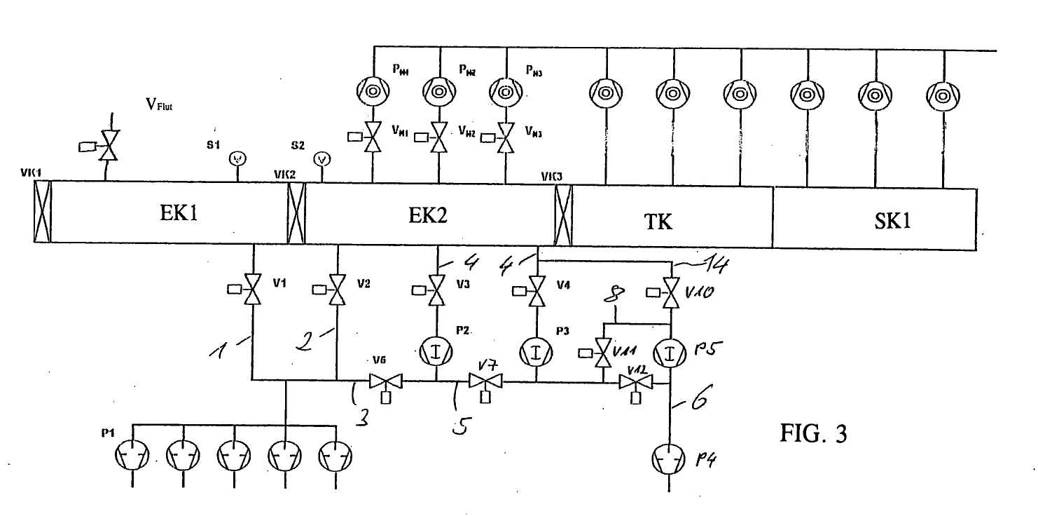

In the alternative embodiment of FIG. 3, which largely corresponds to the embodiment of FIG. 1, and, consequently, will henceforth only be described regarding the differences, with the second pump set, additionally to the Roots pumps P2 and P3, a third Roots pump P5 is parallel integrated, connected with inlet chamber EK2 over an additional conduit 14 and a valve 10 therein disposed. Additionally, in a parallel sense in relation to the third pump P5, a conduit 8 is shown, disposed between the inlet chamber conduit 14 and conduit 5, connecting the outlet side of pumps P2, P3 and P5, and again a valve V11 is integrated in conduit 8. Conduit 8 discharges between valve V10 and pump P5 into conduit 14. Furthermore, a valve V12 is integrated between the inlet of conduit 8 in conduit 5 and inlet of conduit 6 in conduit 5. This bypass set to pump P5, by closing valve V10, as well as valve V12 and opening of valve V11, renders it possible to integrate pump P5 sequentially to Roots pumps P2 and P3, so that pump P5, with the third pump set P4, here formed by a single stage pump set based on a rotary vane pump forming a multistage Roots pump stand.

Consequently, at the moment in which the first pump set P1 no longer is available as a sequentially integrated pumping stage for the second pump set—since the first pump set P1 again has to evacuate inlet chamber EK1—it is feasible to attain a potential, multistage pump set for inlet chamber EK2 by regrouping pump P5, i.e., sequential integration of pump P5 to pumps P2 and P3. Accordingly, before valve V5 or V7 are closed, valves V10 and V12 are being closed and valve V11 will be opened, in order to sequentially integrate pump P5 with pumps P2 and P3. Except for the above, the sequence corresponds to the inlet process in the inlet area of FIG. 1. The advantage of this variant, however, is seen in the fact that during the discharge, i.e., outlet phase with the second pump set P2, P3, P5, by closing valves V10 and V12 and opening valve V11, a three-stage Root pump stand may be formed with the second and third pump set P4 as a forepump unit. The third stage with Roots pumps P2 and P3 may be doubled or halved by opening/closing V7, or may be split up between the first pump set P1 and the third pump set P4, respectively.

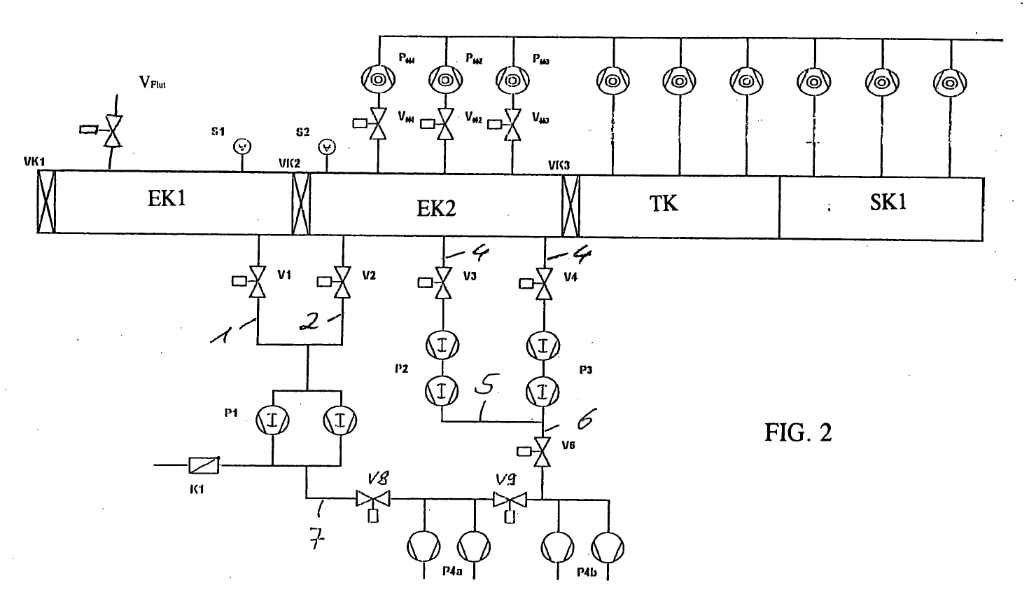

In the embodiment of FIG. 2, the first pump set is formed by two parallel integrated, singled stage and pre-admittance cooled Roots pumps, connected over conduit 1 and valve V1 with inlet chamber EK1 and over conduit 2 and valve V2, are connected with inlet chamber EK2. (The pre-admittance gas cooling is not shown).

The second pump set consists of the double-stage parallel Roots pumps P2 and P3, which again are connected with inlet chamber EK2 over conduits 4 and corresponding valves V3 and V4.

At the discharge side of the first pump set P1 and of the second pump set P2, P3, a third pump set P4a, P4b of parallel integrated, single stage dry-running pumps, for example in the form of axial pumps, is shown, which over conduit 6 is connected with the second pump set P2, P3, with their joint conduit 5, over conduit 7, with the first pump set P1. In conduit 6, there is valve V6 and in conduit 7, valve V8 is shown, so that the corresponding connections may be separated. Additionally, in the connecting conduit between the parallel integrated axial pumps P4a and P4b, a valve V9 is shown. With the embodiment of FIG. 2, both inlet chamber EK1, as well as inlet chamber EK2, may be discharged over multistage pumping stands, and especially due to this disposition, oil-sealed forepumps may be waived, and alternately, in an especially advantageous form, exclusively dry-compressing pumps may be used.

Admission of a substrate into the vacuum treatment plant of FIG. 2 takes place in such a fashion that initially valve lid VK1 of the first inlet chamber EK1 is being opened, and the substrate is being transported into inlet chamber EK1. Subsequently, valve lid VK1 is closed and valve V1 to the first pump set P1 is opened, and the gas transported at high pressure levels, for example 500 to 1000 hPa, contingent upon the forepump level of the third pump set P4, is being evacuated into the atmosphere over discharge lid VK1. As of an acceptance pressure Pü of, for example, 300 hPa, valve V8, or V8 and V9, are being opened, so that a multistage pump set is being provided for discharging said inlet chamber EK1.

Valves V3 and V4 are now being closed, while valve V2 and valve lid VK2 between inlet chamber EK1 and inlet chamber EK2 are being opened. The substrate is now transported from the first inlet chamber EK1 into the second inlet chamber EK2.

Subsequently, valves V6, V3 and V4 are opened and eventually valves V8 and V9 are closed. Then, valve lid VK2 and valve V1 are again closed, so that the admittance chamber, i.e., inlet chamber EK1, is ventilated and valve lid VK1 may be opened, in order that the next substrate may be introduced into inlet chamber EK1.

Subsequently, valves V8 and V2 are closed and V1 is opened to evacuate the first inlet chamber EK1. The high-vacuum pumps P_{H1} to P_{H3}—according to the operation of the first example according to FIG. 1—may be connected with inlet chamber EK2 over valves Vh1 to Vh3, so that valves V3 and V4 may subsequently be closed. When inlet chamber EK2 corresponds to vacuum conditions of sputtering chamber SK1, valve lid VK3 will be opened and substrate will be introduced into the processing area. Also here, evidently, the processes in both load lock chambers EK1 and EK2 partly take place simultaneously.

An advantage of this disposition includes that the first pump set P1, and also the third pump set P4, may be utilized nearly on a 100% basis, i.e., practically over the entire inlet or admission cycle. Additionally, also here chamber valve VK2 may be opened already at higher pressure levels, for example 100 to 400 hPa, especially 250 hPa, which, compared to an opening at approximately 15 hPa, corresponding to the acceptance pressure of Roots pumps P2 and P3, corresponds to an evidently shorter pumping time for discharging inlet chamber EK1, thereby rendering feasible a more compact construction of the corresponding pump stand.

Due to the variable conditions of utilization of a third pump set P4 as a forepump stand, both of the first pump set P1 as well as of the second pump stand P2, P3, also for inlet chamber EK1 and inlet chamber EK2, a multistage pump stand is being provided, for variable utilization. Especially, with all embodiments shown, the pumping capacity, i.e., the absorption capacity, may thus accompany the substrate at the inlet side or generally along the direction of evacuation from atmosphere to vacuum, i.e., according to the local requirements of pumping capacity, so that this results in a considerable capacity increase and time reduction.

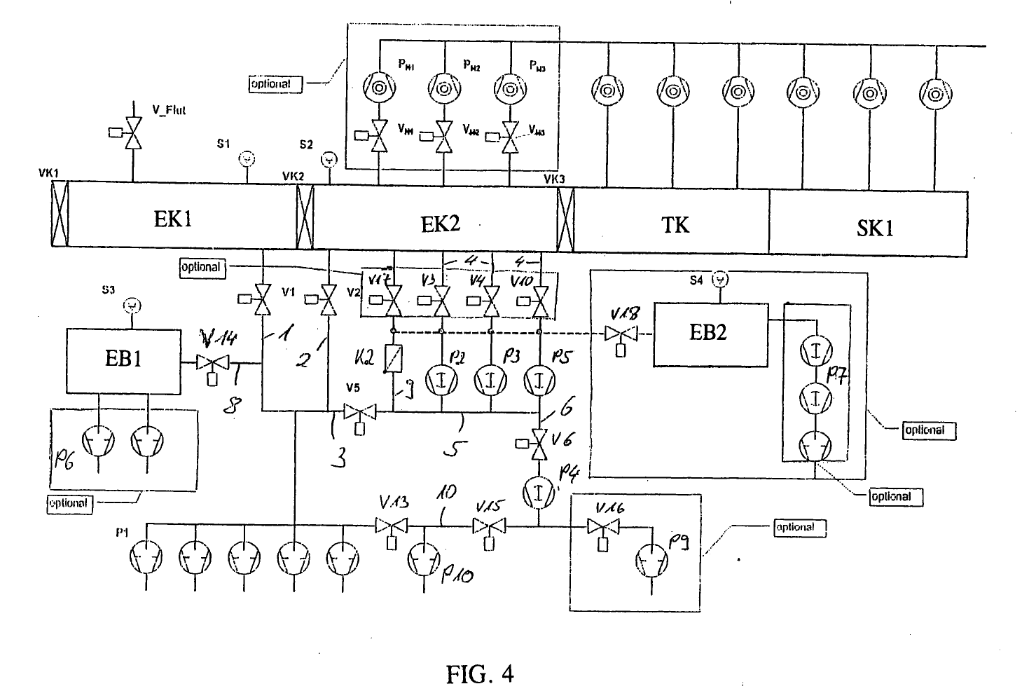

FIG. 4 shows another embodiment of a lock chamber unit according to the invention, which is largely coincident with FIG. 3.

A first difference is to be found in the fact that the second pump set, with the parallel integrated pumps P2, P3 and P5, features no bypass 8 parallel to pump P5, such as in FIG. 3, but, parallel to conduit 4, with which pumps P2, P3 and P5 are connected to the second inlet chamber EK2, a differential pressure bypass lid K2 is provided, connected with the second inlet chamber EK2 over conduit 9 and valve V17. By means of this disposition, it is possible to couple the parallel integrated Roots pumps P2, P3 and P5 with relatively high intake pressure, in order to be able to utilize—according to the adjusted differential pressure—already with high intake pressures, a portion of their absorption capacity for rapid evacuation. Due to a connection of the outlet side of pumps P2, P3 and P5 with the absorption side, over the second inlet chamber EK2, bypass lid K2 foresees that pumps P2, P3 and P5 only have to over-come a differential pressure which may be adjusted at bypass lid K2. For this purpose, for example, said bypass lid may consist of a spring-loaded or weight-loaded valve, which opens towards the direction of the chamber at the occasion of a determined overpressure at the evacuation side of Roots pumps P2, P3 and P5. Valves V3, V4 and V10 may thus be opened, or remain open, at higher absorption pressures and/or the utilization of pre-admittance cooled Roots pumps, which also could be used at higher pressures, may be waived, so that it is possible to reduce the costs for the second pump set, providing, simultaneously, a higher pumping capacity. Furthermore, instead of a differential pressure bypass K2, various differential pressure lids could be provided, for example for each pump P2, P3 or P5, or it would be possible to utilize Roots pumps with integrated bypass lids.

The disposition of said bypass lid K2 offers the additional advantage that valves V17, V3, V4 and V10 during their operation may remain permanently open, i.e., they do not have to be forcibly closed in each cycle, especially when the high-vacuum pumps P_{H1} through P_{H3} are waived. The operation is thus also accordingly simplified.

A second difference of the embodiment of FIG. 4 as compared with the embodiment of FIG. 3 includes that the parallel integrated vacuum pumps of the first pump set P1 may be coupled over a conduit 10 and valves V13 and V15 therein shown, as a sequential stage to the third pump set P4 or parallel to other pumps P9, over valve V16, and P10, over V13. By closing valve V5 and opening valves V6, V13, V15 and eventually V9, it is thus possible to form, during the evacuation stage, a multistage pumping level with the first pump set P1, the fourth pump set P4 and the second pump set P2, P3 and P5. Thus, starting at the two-stage pumping level, without interrupting the pumping capacity, an almost perfect transition to a three-stage pump level may take place, or, in general terms, of an n-stage pumping level, an n+1-stage pumping level may be formed. It is evident that, consequently, pump P9 with valve V16 only could be provided on an optional basis.

Another difference of the embodiment of FIG. 4, as compared to the preceding embodiments, includes that additionally it features an outer buffer unit EB1, which through valve V14 and conduit 8, as well as conduit 1, is connected with the first inlet chamber EK1. Buffer unit EB1 offers a buffering volume, which may be absorbed through the optionally foreseen fifth pump set P6 or through the first pump set P1. With the thus evacuated buffer volume, after opening valves V1 and V14, pressure inside the first inlet chamber EK1 may be suddenly reduced. In this form, it is possible to utilize pumping capacity, i.e., absorption capacity, in periods of time in which pumping capacity, i.e., absorption capacity, for direct evacuation of inlet chambers EK1 and EK2 is not being required or when the additional integration of the fifth pump set P6 and inlet chamber EK1 should not be advantageous, due to pressure conditions. This pumping capacity, i.e., absorption capacity, as it were, is being stored in buffer unit EB1 and afterwards, in case of need, is being offered to the first inlet chamber EK1.

In a similar fashion, also the second inlet chamber EK2 may act as an internal buffer unit, when by opening valves V1 and V2, a pressure equalization is being made between inlet chambers EK1 and EK2, so that also here the pressure declines suddenly. Especially in the case of a reciprocally adjusted combination of a pressure equalization between the first inlet chamber EK1 and buffer unit EB1 and subsequent pressure equalization between the first inlet chamber EK1 and the second inlet chamber EK2, it is possible to attain two stages of a quick pressure reduction, and also here the absorption capacity relative to the second inlet chamber EK2 may be utilized during a large period of time of the transfer process.

Additionally, a second outer buffer unit EB2 may optionally be provided with corresponding optionally foreseen additional sixth pump set P7, by means of which a pressure equalization between the second inlet chamber 2 and the second buffer unit EB2 also provides a sudden pressure reduction. Instead of the sixth pump set P7, the buffer volume of the second buffer unit EB2 may also be evacuated through the second (P2, P3, P5), third (P4) and/or other pump sets already provided for the second inlet chamber EK2, such as, for example, P9.

In the embodiment of FIG. 4, it is also indicated that high-vacuum pumps PH1 through PH3 may be abandoned in all embodiments, and are therefore only optional when over the absorption capacity for the second inlet chamber EK2 a sufficient vacuum may be obtained.

Valves V3, V4, V10 and V17 are designed to be capable of separating the second inlet chamber EK2 from the pump stand and render possible an independent ventilation of the chamber, or of the pump stand, respectively. If it should be considered that this is not required, these valves may also be waived. Valves V3, V4, V10 and V17 are, however, needed in any case, when the second buffer unit EB2 is to be evacuated over the second pump set P2, P3, P5, since then a separation from the second inlet chamber EK2 will be required. However, if the second buffer unit EB2 is to be evacuated only through the sixth pump set P7, the second buffer unit EB2 could also be directly united with the second inlet chamber EK2 by means of V18.

In an embodiment according to FIG. 4, the transfer process takes place in the following way. Initially, valve lid VK1 of the first inlet chamber EK1 is opened and the substrate is transported into the first inlet chamber EK1. Subsequently, valve lid VK1 is closed and valve V1 is opened towards pump stand P1. Valve V14 is open during this process and valves V2, V5 and V13 or V15 are closed. Due to the pressure equalization with the evacuated buffer volume of the first buffer unit EB1, pressure in the first inlet chamber EK1 is suddenly reduced from atmospheric pressure to approximately 400 hPa. V14 is now closed and V2 is opened, so that a second sequential pressure equalization takes place, precisely between the first inlet chamber EK1 and the second evacuated inlet chamber EK2. With approximately identical chamber volumes of the first and second inlet chambers EK1 and EK2, pressure in both chambers is suddenly regulated to approximately 200 hPa. Valve lid VK2 is now opened and the substrate is moved from the first inlet chamber EK1 into the second inlet chamber EK2. During this process, valve V5 is opened and valves V1 and V2 are closed.

Simultaneously, or with reduced delay, valves V6 and V15 and, eventually, V13, are opened and valve V5 is closed, so that there is no longer a bypass towards the third pump set P4, now prevailing a multistage pumping level with pumping stages from the first pump set P1, second pump set P2, P3, P5 and third pump set P4.

Valve lid VK2 is now closed and the first inlet chamber EK1 is ventilated over valve V_{Flut}. Subsequently, valve lid VK1 may be opened and the next substrate may be transported into the first inlet chamber EK1. The optionally provided high-vacuum pumps PH1 through PH3 may now be connected with the second inlet chamber EK2, by means of opening valves VH1 through VH3. In this case, valves V3, V4, V10 and V17 are closed. If no high-vacuum pumps are foreseen on the second inlet chamber EK2, these valves may, if necessary, remain continuously open during operations. Valve lid VK3 may now be opened and substrate may be transferred towards the process area, i.e., into transfer chamber TK. Valves V13 and V15 are closed and valve V14 will be opened, so that the first pump set may evacuate the buffer volume of the first buffer unit EB1. If the fifth pump set P6 is foreseen, the buffer volume of the first buffer unit EB1 may be evacuated jointly through the first pump set P1 and the fifth pump set P6. The inlet process will then be reinitiated.

If, with the lock chamber arrangement of FIG. 4, the second outer buffer unit EB2 is provided, then valve V18 will be opened for pressure equalization between the second inlet chamber EK2 and the previously evacuated buffer volume of the second buffer unit EB2, after substrate has reached the second inlet chamber EK2 and after valve lid VK2 has been closed. Pressure in the second inlet chamber EK2 may thus be suddenly reduced from approximately 30 hPa to 10 hPa.

During transportation of substrate from the second inlet chamber EK2 into transfer chamber TK, valves V3, V4, V10 and V17 are closed, in order to utilize the second pump set with pumps P2, P3 and P5 for evacuating buffer volume of the second buffer unit EB2.

With the solution now proposed, according to an embodiment of FIG. 4, based on the buffer solutions, it is possible to produce the pressure reduction through a double-stage pressure equalization in the first lock chamber within quite short time periods, i.e., periods much smaller than a second, so as to be able to transfer immediately the substrate into the second lock chamber. With a second buffer unit, this effect may also be utilized for the second lock chamber EK2.

The process now presented in the inlet area, in a correspondingly analog fashion may also be utilized for the outlet, i.e., unload area, without the requirement of a closer description, since one skilled in the art may undertake the corresponding adaptation in a simple fashion.

The above description is considered that of the preferred embodiments only. Modification of the invention will occur to those skilled in the art and to those who make or use the invention. Therefore, it is understood that the embodiments shown in the drawings and described above are merely for illustrative purposes and not intended to limit the scope of the invention, which is defined by the following claims as interpreted according to the principles of patent law, including the doctrine of equivalents.

1. A lock chamber device for a vacuum treatment plant comprising:
at least two sequentially arranged lock chambers for carrying out a double-stage or a multi-stage pressure equalization process;
a first pump set for evacuating a first lock chamber of the at least two sequentially arranged lock chambers; and
a second pump set for evacuating a second lock chamber of the at least two sequentially arranged lock chambers;
wherein the first pump set is connected with the first lock chamber and the second lock chamber by a plurality of lockable conduits, so that the first pump set may evacuate either the first or the second or both lock chambers.

2. The lock chamber device according to claim 1, further including:
a third pump set connected to the first pump set and the second pump set through lockable conduits, so that the third pump set may be sequentially integrated either into the first or the second or into both pump sets.

3. The lock chamber device according to claim 1, wherein:
the first pump set is connected with the second pump set by lockable conduits, so that the first pump set may be sequentially integrated with the second pump set.

4. The lock chamber device according to claim 3, further including:
a third pump set connected to the second pump set through lockable conduits, so that the third pump set may be sequentially integrated with the second pump set.

5. The lock chamber device according to claim 1, wherein:
the pump sets comprise parallel and/or sequentially integrated pumps.

6. The lock chamber device according to claim 1, wherein:
the pump sets are selected from the group consisting of oil-sealed and/or dry-compressing vacuum pumps, especially rotary vane pumps, rotary piston pumps, rotary plunger pumps, vacuum roots booster and dry-running pumps.

7. The lock chamber device according to claim 6, wherein:
the pump sets comprise axial pumps and/or Roots pumps.

8. The lock chamber device according to claim 7, wherein:
the pump sets comprise pre-admittance cooled Roots pumps.

9. The lock chamber device according to claim 5, wherein:
the pumps are parallel integrated in one pump set, and the pumps include a lockable bypass through which at least one of the pumps may be connected sequentially relative to the other pump, in order to compose a multistage pumping stand.

10. The lock chamber device according to claim 1, wherein:
at least one of the lock chambers comprises at least one high-vacuum pump fluidly connected thereto by lockable conduits.

11. The lock chamber device according to claim 1, further including:
a bypass lid connected to one of the lock chambers parallel to one of the pump sets;
wherein the one of the lock chambers includes an evacuation side and the one of the pumps sets includes an inlet side and an outlet side; and
wherein the bypass lid is commanded by differential pressure and, in the event of high pressure applied on the evacuation side of the one of the lock chambers, represents a bypass from the outlet side towards the inlet side of pump sets, so that a maximum differential, critical pressure level being applied to the one of the pump sets is not being exceeded and a pumping capacity of the pump set is continuously being utilized on a pressure dependent basis.

12. The lock chamber device according to claim 1, wherein:
the first pump set comprises at least one parallel integrated, single or multistage vacuum pumps;
the first pump set is connected with the first lock chamber through a first conduit having a first valve;
the first pump set is connected with the second lock chamber through a second conduit having a second valve;
the first pump set is connected with the second pump set, a third conduit having a third valve;
the second pump set including at least one parallel integrated, single or multistage vacuum pumps;
the second pump set is connected with the second lock chamber through a fourth conduit having a fourth valve; and
pumps of the second pump set are reciprocally interconnected through a fifth conduit with a fifth valve.

13. The lock chamber device according to claim 12, further including:
a third pump set comprising at least one parallel integrated, single multistage vacuum pump;
wherein the third pump set is connected to an outlet side of the second pump set through a sixth conduit.

14. The lock chamber device according to claim 13, wherein:
the sixth conduit includes a sixth valve.

15. The lock chamber device according to claim 13, wherein:
the third pump set is connected to the second pump set at the fifth conduit.

16. The lock chamber device according to claim 13, wherein:
the first pump set comprises at least one rotary vane pump, the second pump set comprises Roots pumps and the third pump set comprises double-stage Root pump stands or a single-stage pump stand with rotary vane pumps.

17. The lock chamber device according to claim 12, wherein:
a seventh conduit with a seventh valve is located between the fourth conduit and the fifth conduit, so that a parallel integrated pump of the second pump set may be integrated sequentially relative to the other pumps.

18. A lock chamber device for a vacuum treatment plant comprising:
at least two sequentially arranged lock chambers for carrying out a double-stage or a multi-stage pressure equalization process;
a first pump set for evacuating a first lock chamber of the at least two sequentially arranged lock chambers; and
a buffer unit connected with the first lock chamber through lockable conduits.

19. The lock chamber device according to claim 18, wherein:
the buffer unit includes a fifth pump set, which evacuates a buffer volume of the buffer unit.

20. The lock chamber device according to claim 18, wherein:
the first pump set is connected with the buffer unit.

21. The lock chamber device according to claim 18, wherein:
the buffer unit is connected with a second lock chamber of the at least two sequentially arranged lock chambers through lockable conduits.

22. The lock chamber device according to claim 21, further including:
a second buffer unit connected with the second lock chamber through lockable conduits.

23. The lock chamber device according to claim 22, further including:
a sixth pump set connected to the second buffer unit for discharging a buffer volume of the second buffer unit.

24. The lock chamber device according to claim 1, wherein:
the first pump set comprises at least one parallel integrated, single or multistage vacuum pump;
the first pump set is connected with the first lock chamber through a first conduit having a first valve;
the first pump set is connected with the second lock chamber through a second conduit having a second valve;
the second pump set including at least one parallel integrated, single or multistage vacuum pumps;
the second pump set is connected with the second lock chamber through a fourth conduit having a fourth valve;
a discharge side of the second pump set is connected with the first pump set through a sixth conduit having a sixth valve;
the first pump set is connected to a third pump set through an eighth conduit having an eighth valve; and
the third pump set comprises at least one parallel integrated, single or multistage vacuum pump.

25. The lock chamber device according to claim 24, wherein:
the first pump set and the second pump set comprise Roots pumps; and
the third pump set comprises dry-running pumps.

26. The lock chamber device according to claim 25, wherein:
the dry-running pumps of the third pump set comprise axial pumps.

27. The lock chamber device according to claim 1, wherein:
the first and second lock chambers are disposed in a reciprocally adjacent position.

28. The lock chamber device according to claim 1, wherein:
the lock chambers are provided in an inlet and/or outlet area of the device.

29. The lock chamber device according to claim 1, wherein:
the lockable conduits include valves through which the conduits may be locked in a gas-tight position.

30. A process for operating a multistage lock chamber device having at least two sequentially arranged lock chambers for carrying out a double-stage or multi-stage pressure equalization process, comprising:
utilizing a first pump set not only for discharging a first lock chamber, but also for evacuating a second lock chamber; and
evacuating, within one cycle, initially only the first lock chamber, and then subsequently the first and second lock chambers, and finally only the second lock chamber.

31. The process according to claim 30, further including:
evacuating the second lock chamber with a second pump set in addition to the first pump set;
sequentially pumping the second pump set with the first pump set.

32. The process according to claim 30, further including:
evacuating the second lock chamber with a second pump additionally to the first pump set; and
sequentially integrating a third pump set to the first and second pump sets; and
alternately carrying out a pre-pumping action of the first and/or second pump set with the third pump set.

33. The process according to claim 30, wherein:
the at least two sequentially arranged lock chambers carry out a double-stage or multi-stage pressure equalization process; and
further including subjecting the first lock chamber to a sudden pressure reduction by equalizing pressure with an evacuated buffer unit.

34. The process according to claim 30, wherein:
a second lock chamber serves as an internal buffer unit, so that through a sudden pressure equalization between the evacuated second lock chamber and the first lock chamber, a pressure level in the first lock chamber is suddenly reduced.

35. The process according to claim 30, wherein:
a multistage, especially double-stage, pressure equalization takes place through a sequence of pressure equalizations with external and/or internal buffer devices.

36. The process according to claim 30, further including:
reducing pressure in the second lock chamber by equalizing pressure between an evacuated second buffer unit and the second lock chamber.
